(19) United States
(12) Patent Application Publication
(10) Pub. No.: US 2025/0167039 A1
(43) Pub. Date: May 22, 2025

(54) MULTI-SIZED SUBSTRATE FIXTURE

(71) Applicant: Onto Innovation Inc., Wilmington, MA (US)

(72) Inventor: Troy Palm, Eden Prairie, MN (US)

(21) Appl. No.: 18/865,780

(22) PCT Filed: May 16, 2023
(86) PCT No.: PCT/US2023/022369

§ 371 Date: Nov. 14, 2024

Related U.S. Application Data
(60) Provisional application No. 63/342,798, filed on May 17, 2022.

(51) Int. Cl. H01L 21/687

(52) U.S. Cl. CPC H01L 21/68785; H01L 21/68721; H01L 21/68728

(57) ABSTRACT

Various examples include a multi-sized substrate fixture configured to receive and secure various sizes of substrates readily. For example, in various embodiments, the disclosed subject-matter describes a mechanism that readily can be adjusted alternately to receive and secure (e.g., affix) various sizes of substrates, such as a 200 mm wafer and a 300 mm wafer. Other apparatuses and devices are also disclosed.

### CLAIM OF PRIORITY

This patent application claims priority to U.S. Provisional Application Ser. No. 63/342,798, entitled, “MULTI-SIZED SUBSTRATE FIXTURE,” filed 17 May 2022; the disclosure of which is incorporated herein by reference in its entirety.

### TECHNOLOGY FIELD

The disclosed subject-matter is related generally to the field of metrology tools and inspection tools used in the semiconductor and allied industries (e.g., flat-panel display and solar-cell production facilities). More specifically, in various embodiments, the disclosed subject-matter is related to a substrate fixture that can be configured alternately to receive and secure various sizes of substrates, such as, for example, semiconductor wafers.

### BACKGROUND

Various types of substrate types and sizes are frequently used within the same fabrication facility. Such types and sizes include, for example, 200 mm and 300 mm diameter semiconductor (e.g., silicon) wafers. However, there are currently no substrate fixtures that can be configured readily to handle multiple substrate sizes alternately (e.g., a 200 mm wafer and a 300 mm wafer) and different shapes of substrates (e.g., round wafers and rigid flat-panel displays).

### SUMMARY

This document describes, among other things, an apparatus that can be configured readily to receive and secure various sizes of substrates. For example, in various embodiments, the disclosed subject-matter describes a mechanism that readily can be adjusted alternately to receive and secure (e.g., affix or clamp) and release (e.g., unclamp) various sizes and shapes of substrates, such as a 200 mm round wafer and a 300 mm round wafer.

In various embodiments described herein, the disclosed subject-matter is an apparatus to accept at least two different sizes of substrates. The apparatus includes at least two sub-assemblies. Each of the sub-assemblies has a set of substrate-edge grippers configured to grip a respective edge on one of the at least two different sizes of substrates. The set of substrate-edge grippers includes at least one edge gripper having a movable portion to clamp and unclamp one of the at least two different sizes of substrates. A substrate-adjustment device is arranged to position at least one of the at least two sub-assemblies, alternately, in an extended position and a retracted position. The extended position can accommodate a smaller of the at least two sizes of substrates.

In various embodiments described herein, the disclosed subject-matter is a multi-sized substrate fixture to accept at least two different sizes of substrates. The multi-sized substrate fixture includes a small-substrate-size sub-assembly to affix a smaller one of the at least two different sizes of substrates. A first plurality of substrate-edge grippers is mechanically coupled to the small-substrate-size sub-assembly. The fixture also includes a large-substrate-size sub-assembly configured to affix a larger one of the at least two different sizes of substrates. A second plurality of substrate-edge grippers is mechanically coupled to the large-substrate-size sub-assembly. The small-substrate-size sub-assembly is mounted concentrically with the large-substrate-size sub-assembly.

In various embodiments described herein, the disclosed subject-matter is a multi-sized substrate fixture to accept at least two different sizes of substrates. The multi-sized substrate fixture includes a small-substrate-size sub-assembly to affix a smaller one of the at least two different sizes of substrates. A first plurality of substrate-edge grippers is mechanically coupled to the small-substrate-size sub-assembly. The fixture also includes a large-substrate-size sub-assembly configured to affix a larger one of the at least two different sizes of substrates. The first plurality of substrate-edge grippers is arranged to be extended and retracted through the large-substrate-size sub-assembly. A second plurality of substrate-edge grippers is mechanically coupled to the large-substrate-size sub-assembly. The small-substrate-size sub-assembly is mounted concentrically with the large-substrate-size sub-assembly.

### BRIEF DESCRIPTION OF FIGURES

Various ones of the appended drawings merely illustrate example implementations of the present disclosure and should not be considered as limiting a scope of the disclosure.

FIG. 1 shows a top-perspective view of an example of a multi-sized substrate fixture, in accordance with various embodiments of the disclosed subject-matter;

FIG. 2 shows an embodiment of a multi-sized substrate fixture having substrate-edge grippers for two different sizes of substrates; FIG. 2 is a bottom-perspective view of an example of the multi-sized substrate fixture of FIG. 1, in accordance with various embodiments of the disclosed subject-matter;

FIG. 3 shows a top-perspective view of an example of a multi-sized substrate fixture with additional details of the multi-sized substrate fixture of FIG. 1; FIG. 3 is an embodiment of the multi-sized substrate fixture arranged to hold a smaller of the two substrate sizes, in accordance with various embodiments of the disclosed subject-matter;

FIG. 4 shows a bottom-perspective view of an example of the multi-sized substrate fixture of FIG. 1; FIG. 4 shows the multi-sized substrate fixture arranged to hold a smaller of the two substrate sizes in accordance with various embodiments of the disclosed subject-matter;

FIG. 5 shows a top-perspective view of an example of a multi-sized substrate fixture with additional details of the multi-sized substrate fixture of FIG. 1; FIG. 5 is an embodiment of the multi-sized substrate fixture arranged to hold a larger of the two substrate sizes, in accordance with various embodiments of the disclosed subject-matter;

FIG. 6 shows a bottom-perspective view of an example of the multi-sized substrate fixture of FIG. 1; FIG. 6 shows the multi-sized substrate fixture arranged to hold a larger of the two substrate sizes in accordance with various embodiments of the disclosed subject-matter;

FIG. 7A shows a cross-sectional view of the multi-sized substrate fixture of FIG. 1, in accordance with various embodiments of the disclosed subject-matter; and

FIG. 7B shows a portion of the cross-sectional view of the multi-sized substrate fixture shown in FIG. 7, in accordance with various embodiments of the disclosed subject-matter.

### DETAILED DESCRIPTION

The disclosed subject-matter is directed to an apparatus that can readily be configured, alternately, to receive and secure (e.g., affix) various sizes and shapes of substrates.

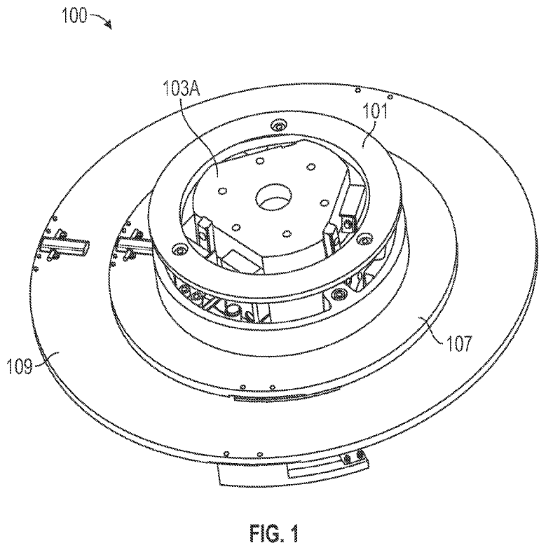

For example, with reference now to FIG. 1, a top-perspective view of an example of a multi-sized substrate fixture 100, in accordance with various embodiments of the disclosed subject-matter is shown. FIG. 1 is shown to include a substrate size-change ring 101, a small-substrate-size sub-assembly 107 and a large-substrate-size sub-assembly 109. As shown in FIG. 1, the small-substrate-size sub-assembly 107, arranged to accommodate a smaller of at least two sizes of substrates, is mounted concentrically within the large-substrate-size sub-assembly 109.

As described below, the small-substrate-size sub-assembly 107 can be moved to extend or retract edge grippers on to which a smaller substrate may be affixed temporarily. The large-substrate-size sub-assembly 109 includes edge grippers on to which a larger substrate may be affixed temporarily. The edge grippers are also described in detail, below.

FIG. 1 is also shown to include a topside view of a motor mount 103A. The motor mount 103A is arranged mechanically to couple a motor (e.g., an electric motor or an air bearing) to rotate a substrate affixed to the multi-sized substrate fixture 100. In this embodiment, the multi-sized substrate fixture 100 is arranged such that a substrate is mounted to a bottom side of the multi-sized substrate fixture 100, as described in more detail below.

Although not shown explicitly, various types of metrology tools or inspection tools may be mounted beneath, above, or surrounding the multi-sized substrate fixture 100. In various embodiments, the metrology tools or inspection tools may be arranged to measure features on or inspect at least portions of, for example, a backside of the substrate while the substrate is rotated. However, in other embodiments, the frontside of the substrate may be measured or inspected as well. Also, although the multi-sized substrate fixture 100 is shown with a substrate being affixed to a lower-portion (e.g., lower portion) of the multi-sized substrate fixture 100, no such limitation is intended. The multi-sized substrate fixture 100 can be operated and oriented in a variety of positions.

In one embodiment, should an end-user of the multi-sized substrate fixture 100 desire to measure or inspect an entire surface or a portion of the entire surface of the substrate, the measurement or inspection may occur as a series of concentric rings while the substrate is rotated above the tool. Each concentric ring can involve moving a measurement or inspection component of the tool in a direction that is radially outward (or inward) with regard to the substrate.

In other embodiments, should an end-user of the multi-sized substrate fixture 100 desire to measure or inspect an entire surface or a portion of the entire surface of the substrate, the measurement or inspection may occur as an Archimedes spiral while the substrate is rotated above the tool. Consequently, the substrate may be measured or inspected while continually moving a measurement or inspection component of the tool in a direction that is radially outward (or inward) with regard to the substrate.

Suitable substrates that can be affixed to the multi-sized substrate fixture 100 may comprise, for example, various types of substrates, such as a wafer comprising elemental semiconductors (e.g., silicon or germanium), a wafer comprising compound semiconductors (e.g., gallium arsenide (GaAs) or gallium nitride (GaN)), or variety of other substrate types known in the art (including conductive, semiconductive, and non-conductive substrates). Consequently, the substrate may comprise, for example, any one or more of 400 mm, 300 mm, 200 mm, 150 mm, 125 mm, and 100 mm round substrates (e.g., wafers), including opaque (e.g., at visible wavelengths), clear, and bonded substrates.

Although the multi-sized substrate fixture 100 is described herein for mounting either a 200 mm or a 300 mm round substrates (e.g., wafers), such a limitation is not intended. Moreover, the multi-sized substrate fixture 100 may be arranged for accepting a non-round substrate, such as a flat-panel display. As described herein, accepting non-round substrates may include increasing a number of mounting fingers (e.g., from three to four or more), such a configuration is considered within a scope of the disclosed subject-matter. Further, the multi-sized substrate fixture 100 may be configured for being able to accept three or more substrate sizes by exposing or retracting certain groups of fingers. However, the disclosed subject-matter is described herein for mounting a 200 mm substrate or a 300 mm substrate so that a person of ordinary skill in the art will readily understand the disclosed subject-matter. Upon reading and understanding the disclosed subject-matter, the person of ordinary skill in the art will recognize how the concepts and mechanisms described herein may be expanded to accept more than two size of substrates or accept non-round substrates.

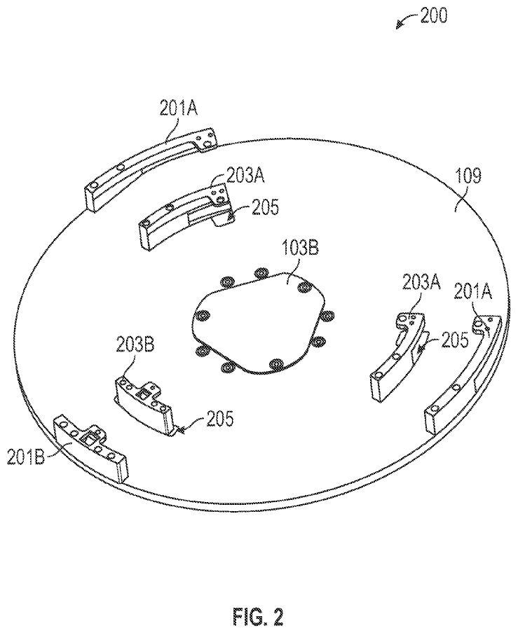

FIG. 2 shows an embodiment of the disclosed subject-matter having substrate-edge grippers for two different sizes of substrates. FIG. 2 is a bottom-perspective view 200 of an example of the multi-sized substrate fixture 100 of FIG. 1, in accordance with various embodiments of the disclosed subject-matter. In this example, two outer fixed edge-grippers 201A and a movable outer edge-gripper 201B for gripping an edge of, for example, a 300 mm substrate are shown. Also, two inner fixed edge-grippers 203A and a movable inner edge-gripper 203B for gripping an edge of, for example, a 200 mm substrate are shown. The edge-grippers 203A, 203B may be extended through slots 205 formed in the large-substrate-size sub-assembly 109 as described in more detail, below.

In various embodiments, an end effector of a robotic substrate-transfer tool (not shown) may press the substrate up against the two fixed edge-grippers. The movable edge-gripper may then be actuated (e.g., acted upon) to provide a force (e.g., a spring-loaded activation force, a solenoid-based activation force, a magnetically-based activation force, a pneumatically-based activation force, etc.) against an opposing portion of the edge of the substrate prior to removal of the end effector of the robot. FIG. 2 is also shown to include a bottom side view 103B of the motor mount 103A of FIG. 1.

In various embodiments, and as described in more detail below, one or both of the two fixed edge-grippers 201A may also be movable. In such embodiments, the movable edge-gripper may or may not have a portion that can be activated to press against the substrate, thereby securing the substrate in a known location. Therefore, the terms “fixed” and “movable” are provided simply to provide a more readily understandable description of the disclosed subject-matter.

As described above, the substrates are described as “300 mm” and “200 mm” merely to convey readily two of the sizes that may be accepted by the multi-sized substrate fixture 100 of FIG. 1. Other sizes, and more than two sizes, of substrates may be accepted by the multi-sized substrate fixture 100 depending upon a configuration of the multi-sized substrate fixture 100. As is further described above, other shapes of substrates, such as square, rectangular, or otherwise polygonal shapes, may be accepted by the multi-sized substrate fixture 100. Such non-round shapes may benefit from additional ones of the fixed edge-grippers and/or a movable edge-gripper. For example, four or more edge grippers (e.g., two fixed edge-grippers and two movable edge-grippers) may provide a more stable support for a square substrate or a rectangular substrate.

With continuing reference to FIG. 2, the bottom-perspective view 200 of an example of the multi-sized substrate fixture 100 of FIG. 1 is shown with all of the inner edge-grippers, 203A, 203B in an extended position. The extended position, as described in more detail below, allows for the 200 mm substrate to be affixed to the inner edge-grippers, 203A, 203B of the multi-sized substrate fixture 100 of FIG. 1. The inner edge-grippers, 203A, 203B are extended through or from the large-substrate-size sub-assembly 109.

In various embodiments of the multi-sized substrate fixture 100 of FIG. 1, the outer edge-grippers 201A, 201B are always extended and therefore not retractable. Consequently, in these embodiments, the 300 mm substrate is mounted, if desired, after the inner edge-grippers, 203A, 203B are retracted. Therefore, a position of the 200 mm substrates and the 300 mm substrates is always in a substantially common plane (e.g., co-planar). The common plane allows, for example, a focus plane or point of the metrology tools and the inspection tools to remain fixed. Consequently, the metrology tools and the inspection tools do not need to be refocused or realigned when switching the multi-sized substrate fixture 100 from 200 mm to 300 mm configurations.

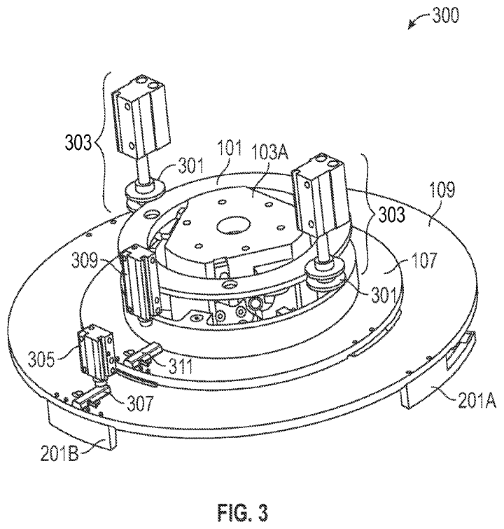

FIG. 3 shows a top-perspective view 300 with additional details of the multi-sized substrate fixture 100 of FIG. 1. FIG. 3 is an embodiment of the multi-sized substrate fixture 100 arranged to hold a smaller of the two substrate sizes (e.g., the 200 mm substrate), in accordance with various embodiments of the disclosed subject-matter. FIG. 3 is shown to include a pair of substrate-size adjustment mechanisms 303, with each of the substrate-size adjustment mechanisms 303 including a ring-adjustment device 301. The ring-adjustment device 301 allows the substrate-size adjustment mechanisms 303 to retract or extend the small-substrate-size sub-assembly 107 by the substrate size-change ring 101 (which is mechanically coupled to the small-substrate-size sub-assembly 107). Although the ring-adjustment device 301 is shown as being round, there is no requirement for this shape. Therefore, the ring-adjustment device may also be considered a substrate-adjustment device. The ring-adjustment devices 301 may move the substrate size-change ring 101 such that the inner edge-grippers 203A, 203B (see FIG. 2) are extended or retracted. In embodiments, if the substrate size-change ring 101 is not being moved, the ring-adjustment devices 301 do not need to contact the substrate size-change ring 101 while the substrate is being rotated.

In various embodiments, the actuation force from the substrate-size adjustment mechanisms 303 through the ring-adjustment devices 301 to the substrate size-change ring 101 may be applied by a number of different means. For example, the actuation force may be comprised by one or more of the following forces including an electrical force (e.g., applied through a solenoid), a magnetic force, a pneumatic force, or a variety of other means. Further, although only two of the substrate-size adjustment mechanisms 303 are shown, more than two of the adjustment mechanisms may be used in various embodiments. For example, if the multi-sized substrate fixture 100 is configured to affix large rectangular flat-panel displays, then three or more of the c 303 may be used.

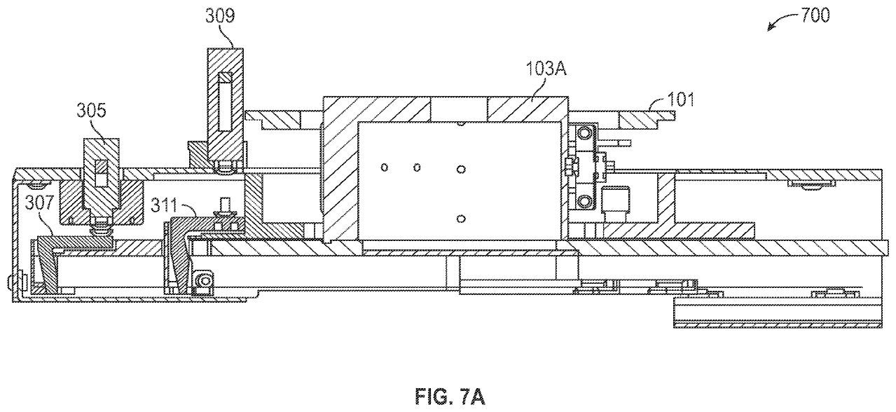

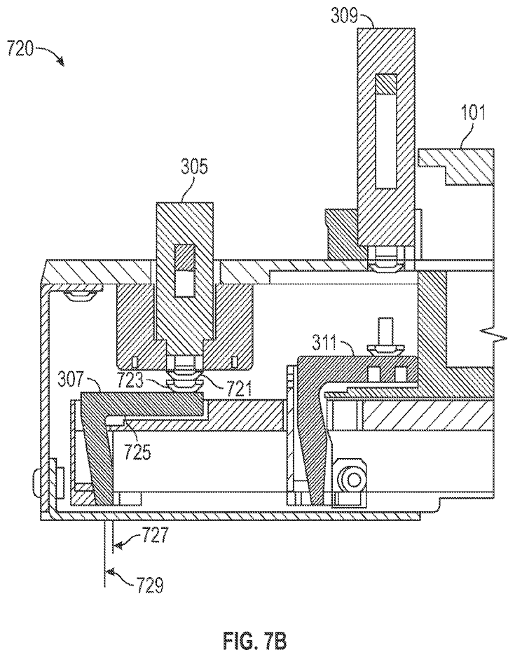

FIG. 3 is also shown to include a movable outer edge-gripper actuation mechanism 305 and a movable inner edge-gripper actuation mechanism 309. In this embodiment, the edge-gripper actuation mechanisms 305, 309 are arranged to provide an actuation force to respective substrate-gripper actuation pads 307, 311. The edge-gripper actuation mechanisms 305, 309 are described in more detail with reference to FIGS. 7A and 7B, below. The edge-gripper actuation mechanisms 305, 309 may be activated by a number of different forces including, for example, an electrical force (e.g., applied through a solenoid), a magnetic force, a pneumatic force, or a variety of other means.

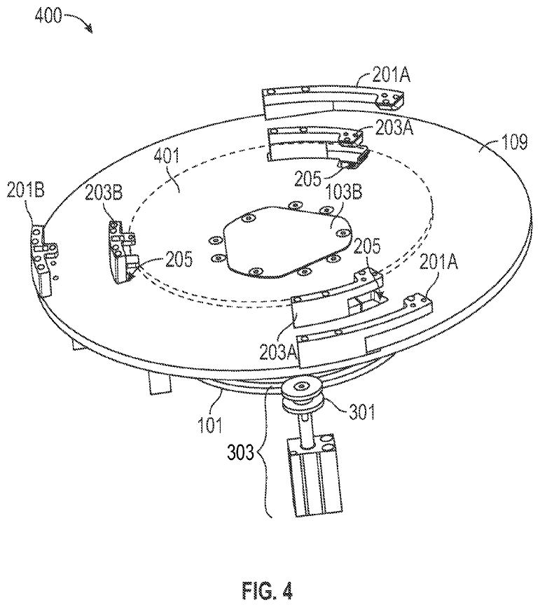

FIG. 4 shows a bottom-perspective view 400 of an example of the multi-sized substrate fixture 100 of FIG. 1. With concurrent reference to FIG. 3, FIG. 4 shows the multi-sized substrate fixture 100 arranged to hold a smaller of the two substrate sizes in accordance with various embodiments of the disclosed subject-matter. FIG. 4 is shown to include a 200 mm substrate 401 being gripped by extended ones of the inner edge-grippers 203A, 203B. In this embodiment, as described above, the outer edge-grippers 201A, 201B are fixed. Since the 200 mm substrate 401 has a smaller diameter than a diameter on which the inner edge-grippers 203A, 203B are arranged, there is no reason to retract the outer edge-grippers 201A, 201B at any time.

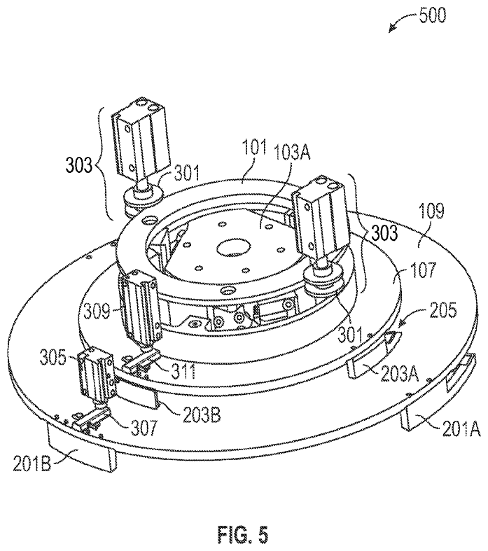

FIG. 5 shows a top-perspective view 500 with additional details of the multi-sized substrate fixture 100 of FIG. 1. FIG. 5 is an embodiment of the multi-sized substrate fixture 100 arranged to hold a larger of the two substrate sizes, in accordance with various embodiments of the disclosed subject-matter. In this example, the small-substrate-size sub-assembly 107 has been retracted by the substrate size-change ring 101 so as to accommodate 300 mm substrates that is in a plane substantially co-planar with the 200 mm substrate 401, which is now removed. The inner edge-grippers 203A, 203B can be seen in FIG. 5 as they have been retracted through the slots 205.

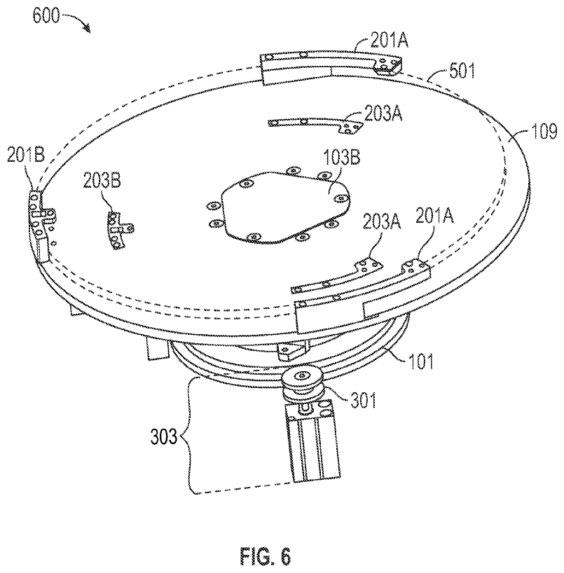

FIG. 6 shows a bottom-perspective view 600 of an example of the multi-sized substrate fixture 100 of FIG. 1. With concurrent reference to FIG. 5, FIG. 6 shows the multi-sized substrate fixture arranged to hold a larger of the two substrate sizes in accordance with various embodiments of the disclosed subject-matter. FIG. 6 is shown to include a 300 mm substrate 501 being gripped by the outer edge-grippers 201A, 201B. In this embodiment, as described above, the outer edge-grippers 201A. 201B are fixed. Since the 300 mm substrate 501 has a larger diameter than a diameter on which the inner edge-grippers 203A, 203B are arranged, the inner edge-grippers 203A, 203B are retracted, as described above, so as not to interfere with a placement of the 300 mm substrate 501.

FIG. 7A shows a cross-sectional view 700 of the multi-sized substrate fixture 100 of FIG. 1, in accordance with various embodiments of the disclosed subject-matter. The cross-sectional view 700 provides an overall context of the multi-sized substrate fixture 100 to provide more detail of an operation of the edge-gripper actuation mechanisms 305, 309 providing an actuation force to the respective one of the substrate-gripper actuation pads 307, 311.

FIG. 7B shows a portion 720 of the cross-sectional view 700 of the multi-sized substrate fixture 100 shown in FIG. 7, in accordance with various embodiments of the disclosed subject-matter. In this example, and with concurrent reference to FIG. 3, the small-substrate-size sub-assembly 107 of FIG. 3 has been lowered via the substrate size-change ring 101, thereby extending the inner edge-grippers 203A, 203B to accommodate a 200 mm substrate. However, a similar operation would occur when a 300 mm substrate is being affixed by the outer edge-grippers 201A, 201B.

For additional clarity however, an operation of the outer edge-grippers 201A, 201B is now described. For example, when a substrate is being loaded into the multi-sized substrate fixture 100, an actuation force (described above) is applied to the outer edge-gripper actuation mechanism 305 to place a plunger in a first position 721. In the first position 721, the substrate-gripper actuation pad 307 applies a force to the plunger of the edge-gripper actuation mechanism 305. The substrate-gripper actuation pad 307 rotates around a pivot point 725 and moves the substrate-gripper actuation pad 307 to a substrate-release position 729. In the second position 723, the substrate-gripper actuation pad 307 releases a force from the plunger of the edge-gripper actuation mechanism 305.

Once the substrate is loaded into the multi-sized substrate fixture 100, another actuation force (e.g., via a spring-return force) is applied to place the substrate-gripper actuation pad 307 in a substrate-clamp position 727. The end effector of the robot (not shown) that placed the substrate can then be withdrawn.

Although the substrate-gripper actuation pad 307 is described as having a pivot point 725, there are many other means to release or clamp a substrate. For example, an actuation force may be applied, or released, from a side position of the substrate. In this embodiment, the substrate-gripper actuation pad 307 may be located on a lower (e.g., bottom) portion of the multi-sized substrate fixture 100 rather than being activated from above.

As used herein, the term “or” may be construed in an inclusive or exclusive sense. Further, other embodiments will be understood by a person of ordinary skill in the art based upon reading and understanding the disclosure provided. Moreover, the person of ordinary skill in the art will readily understand that various combinations of the techniques and examples provided herein may all be applied in various combinations.

Throughout this specification, plural instances may implement components, operations, or structures described as a single instance. Although individual operations are illustrated and described as separate operations, one or more of the individual operations may be performed concurrently, and, unless otherwise stated, nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Further, although not shown explicitly but understandable to a skilled artisan, each of the various arrangements, quantities, and number of elements may be varied (e.g., the number and types of edge grippers and activation mechanisms). Additionally, elements to detect a presence or lack of the substrate may be included. For example, such a “substrates-presence sensor” may be located on a lower portion of the multi-sized substrate fixture. Such a sensor may comprise, for example, an optical sensor including an LED directed toward an LED sensor. If the beam from the LED is not received by the LED sensor, the substrate is mounted or affixed in a correct position. Moreover, each of the examples shown and described herein is merely representative of one possible configuration and should not be taken as limiting the scope of the disclosure.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of operations, systems, and processes have been described, these methods, operations, systems, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain the nature of the technical disclosure quickly. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

The description provided herein includes illustrative examples, devices, and apparatuses that embody various aspects of the matter described in this document. In the description, for purposes of explanation, numerous specific details are set forth in order to provide an understanding of various embodiments of the matter discussed. It will be evident however, to those of ordinary skill in the art, that various embodiments of the disclosed subject-matter may be practiced without these specific details. Further, well-known structures, materials, and techniques have not been shown in detail, so as not to obscure the various illustrated embodiments. As used herein, the terms “about,” “approximately,” and “substantially” may refer to values that are, for example, within ±10% of a given value or range of values.

### The Following Numbered Examples are Specific Embodiments of the Disclosed Subject Matter

Example 1: In an exemplary embodiment, the disclosed subject-matter is an apparatus to accept at least two different sizes of substrates. The apparatus includes at least two sub-assemblies. Each of the sub-assemblies has a set of substrate-edge grippers configured to grip a respective edge on one of the at least two different sizes of substrates. The set of substrate-edge grippers includes at least one edge gripper having a movable portion to clamp and unclamp one of the at least two different sizes of substrates. A substrate-adjustment device is arranged to position at least one of the at least two sub-assemblies, alternately, in an extended position and a retracted position. The extended position can accommodate a smaller of the at least two sizes of substrates.

Example 2: The apparatus of Example 1, further including at least one edge-gripper actuation mechanism coupled to each of at least two sub-assemblies to provide an actuation to the at least one edge gripper having a movable portion.

Example 3: The apparatus of either of the preceding Examples, wherein each of the at least two different sizes of substrates are alternately configured to be mounted in a substantially common plane with one another.

Example 4: The apparatus of any one of the preceding Examples, wherein a portion of the set of substrate-edge grippers is configured to be extended and retracted through a larger of the at least two sub-assemblies, the portion of the set of substrate-edge grippers being configured to accept a smaller of the at least two different sizes of substrates.

Example 5: The apparatus of any one of the preceding Examples, further including a substrate size-change ring coupled to one of the at least two sub-assemblies, the substrate size-change ring to be activated by a plurality of substrate-size adjustment mechanisms.

Example 6: The apparatus of Example 5, wherein each of the plurality of the substrate-size adjustment mechanisms includes a ring-adjustment device, the ring-adjustment device configured to allow the substrate-size adjustment mechanisms to retract and extend a smaller of the at least two sub-assemblies by acting on the substrate size-change ring, which is mechanically coupled to the smaller of the at least two sub-assemblies.

Example 7: The apparatus of Example 6, wherein the ring-adjustment device is configured to retract and extend a smaller of the at least two sub-assemblies by an application of an electrical force to the ring-adjustment device.

Example 8: The apparatus of Example 6, wherein the ring-adjustment device is configured to retract and extend a smaller of the at least two sub-assemblies by an application of a magnetic force to the ring-adjustment device.

Example 9: The apparatus of Example 6, wherein the ring-adjustment device is configured to retract and extend a smaller of the at least two sub-assemblies by an application of a pneumatic force to the ring-adjustment device.

Example 10: The apparatus of any one of the preceding Examples, further including a motor mount coupled to the at least two sub-assemblies and configured to rotate a substrate affixed to the apparatus.

Example 11: The apparatus of any one of the preceding Examples, wherein a smaller one of the at least two sub-assemblies arranged to accommodate the smaller of the at least two sizes of substrates is mounted concentrically within a larger one of the at least two sub-assemblies.

Example 12: In an exemplary embodiment, the disclosed subject-matter is a multi-sized substrate fixture to accept at least two different sizes of substrates. The multi-sized substrate fixture includes a small-substrate-size sub-assembly to affix a smaller one of the at least two different sizes of substrates. A first plurality of substrate-edge grippers is mechanically coupled to the small-substrate-size sub-assembly. The fixture also includes a large-substrate-size sub-assembly configured to affix a larger one of the at least two different sizes of substrates. A second plurality of substrate-edge grippers is mechanically coupled to the large-substrate-size sub-assembly. The small-substrate-size sub-assembly is mounted concentrically with the large-substrate-size sub-assembly.

Example 13: The multi-sized substrate fixture of Example 12, wherein the small-substrate-size sub-assembly is configured to be moved to extend and retract the substrate-edge grippers on to which a smaller substrate may be affixed temporarily.

Example 14: The multi-sized substrate fixture of either of Example 12 or Example 13, wherein the multi-sized substrate fixture is configured to affix the smaller one of the at least two different sizes of substrates and the larger one of the at least two different sizes of substrates separately.

Example 15: The multi-sized substrate fixture of any one of Example 12 through Example 14, wherein each of the first plurality of substrate-edge grippers and the second plurality of substrate-edge grippers includes at least one edge gripper having a movable portion.

Example 16: The multi-sized substrate fixture of Example 15, further including at least one edge-gripper actuation mechanism coupled to each of the small-substrate-size sub-assembly and the large-substrate-size sub-assembly to provide an actuation to the at least one edge gripper having a movable portion.

Example 17: The multi-sized substrate fixture of any one of Example 12 through Example 16, wherein each of the at least two different sizes of substrates are alternately configured to be mounted in a substantially common plane with one another.

Example 18: The multi-sized substrate fixture of any one of Example 12 through Example 17, wherein the first plurality of substrate-edge grippers is configured to be extended and retracted through the large-substrate-size sub-assembly.

Example 19: The multi-sized substrate fixture of any one of Example 12 through Example 18, further including a substrate size-change ring coupled to the small-substrate-size sub-assembly, the substrate size-change ring to be activated by a plurality of substrate-size adjustment mechanisms.

Example 20: The multi-sized substrate fixture of Example 19, wherein each of the plurality of the substrate-size adjustment mechanisms includes a ring-adjustment device, the ring-adjustment device configured to allow the substrate-size adjustment mechanisms to retract and extend the small-substrate-size sub-assembly by acting on the substrate size-change ring, which is mechanically coupled to the small-substrate-size sub-assembly.

Example 21: The multi-sized substrate fixture of any one of Example 12 through Example 20, further including a motor mount coupled to the small-substrate-size sub-assembly and the large-substrate-size sub-assembly, the motor mount being configured to rotate a substrate affixed to the multi-sized substrate fixture.

Example 22: In an exemplary embodiment, the disclosed subject-matter is a multi-sized substrate fixture to accept at least two different sizes of substrates. The multi-sized substrate fixture includes a small-substrate-size sub-assembly to affix a smaller one of the at least two different sizes of substrates. A first plurality of substrate-edge grippers is mechanically coupled to the small-substrate-size sub-assembly. The fixture also includes a large-substrate-size sub-assembly configured to affix a larger one of the at least two different sizes of substrates. The first plurality of substrate-edge grippers is arranged to be extended and retracted through the large-substrate-size sub-assembly. A second plurality of substrate-edge grippers is mechanically coupled to the large-substrate-size sub-assembly. The small-substrate-size sub-assembly is mounted concentrically with the large-substrate-size sub-assembly.

What is claimed:

1. An apparatus to accept at least two different sizes of substrates, the apparatus comprising:
at least two sub-assemblies, each of the sub-assemblies having a set of substrate-edge grippers configured to grip a respective edge on one of the at least two different sizes of substrates, the set of substrate-edge grippers including at least one edge gripper having a movable portion to clamp and unclamp one of the at least two different sizes of substrates; and
a substrate-adjustment device configured alternately to position at least one of the at least two sub-assemblies in an extended position and a retracted position, the extended position being arranged to accommodate a smaller of the at least two sizes of substrates.

2. The apparatus of claim 1, further comprising at least one edge-gripper actuation mechanism coupled to each of at least two sub-assemblies to provide an actuation to the at least one edge gripper having a movable portion.

3. The apparatus of claim 1, wherein each of the at least two different sizes of substrates are alternately configured to be mounted in a substantially common plane with one another.

4. The apparatus of claim 1, wherein a portion of the set of substrate-edge grippers is configured to be extended and retracted through a larger of the at least two sub-assemblies, the portion of the set of substrate-edge grippers being configured to accept a smaller of the at least two different sizes of substrates.

5. The apparatus of claim 1, further comprising a substrate size-change ring coupled to one of the at least two sub-assemblies, the substrate size-change ring to be activated by a plurality of substrate-size adjustment mechanisms.

6. The apparatus of claim 5, wherein each of the plurality of the substrate-size adjustment mechanisms includes a ring-adjustment device, the ring-adjustment device configured to allow the substrate-size adjustment mechanisms to retract and extend a smaller of the at least two sub-assemblies by acting on the substrate size-change ring, which is mechanically coupled to the smaller of the at least two sub-assemblies.

7. The apparatus of claim 6, wherein the ring-adjustment device is configured to retract and extend a smaller of the at least two sub-assemblies by an application of an electrical force to the ring-adjustment device.

8. The apparatus of claim 6, wherein the ring-adjustment device is configured to retract and extend a smaller of the at least two sub-assemblies by an application of a magnetic force to the ring-adjustment device.

9. The apparatus of claim 6, wherein the ring-adjustment device is configured to retract and extend a smaller of the at least two sub-assemblies by an application of a pneumatic force to the ring-adjustment device.

10. The apparatus of claim 1, further comprising a motor mount coupled to the at least two sub-assemblies and configured to rotate a substrate affixed to the apparatus.

11. The apparatus of claim 1, wherein a smaller one of the at least two sub-assemblies arranged to accommodate the smaller of the at least two sizes of substrates is mounted concentrically within a larger one of the at least two sub-assemblies.

12. A multi-sized substrate fixture to accept at least two different sizes of substrates, the multi-sized substrate fixture comprising:
a small-substrate-size sub-assembly configured to affix a smaller one of the at least two different sizes of substrates;
a first plurality of substrate-edge grippers mechanically coupled to the small-substrate-size sub-assembly;
a large-substrate-size sub-assembly configured to affix a larger one of the at least two different sizes of substrates; and
a second plurality of substrate-edge grippers mechanically coupled to the large-substrate-size sub-assembly, the small-substrate-size sub-assembly mounted concentrically with the large-substrate-size sub-assembly.

13. The multi-sized substrate fixture of claim 12, wherein the small-substrate-size sub-assembly is configured to be moved to extend and retract the substrate-edge grippers on to which a smaller substrate may be affixed temporarily.

14. The multi-sized substrate fixture of claim 12, wherein the multi-sized substrate fixture is configured to affix the smaller one of the at least two different sizes of substrates and the larger one of the at least two different sizes of substrates separately.

15. The multi-sized substrate fixture of claim 12, wherein each of the first plurality of substrate-edge grippers and the second plurality of substrate-edge grippers includes at least one edge gripper having a movable portion.

16. The multi-sized substrate fixture of claim 15, further comprising at least one edge-gripper actuation mechanism coupled to each of the small-substrate-size sub-assembly and the large-substrate-size sub-assembly to provide an actuation to the at least one edge gripper having a movable portion.

17. The multi-sized substrate fixture of claim 12, wherein each of the at least two different sizes of substrates are alternately configured to be mounted in a substantially common plane with one another.

18. The multi-sized substrate fixture of claim 12, wherein the first plurality of substrate-edge grippers is configured to be extended and retracted through the large-substrate-size sub-assembly.

19. The multi-sized substrate fixture of claim 12, further comprising a substrate size-change ring coupled to the small-substrate-size sub-assembly, the substrate size-change ring to be activated by a plurality of substrate-size adjustment mechanisms.

20. The multi-sized substrate fixture of claim 19, wherein each of the plurality of the substrate-size adjustment mechanisms includes a ring-adjustment device, the ring-adjustment device configured to allow the substrate-size adjustment mechanisms to retract and extend the small-substrate-size sub-assembly by acting on the substrate size-change ring, which is mechanically coupled to the small-substrate-size sub-assembly.

21. The multi-sized substrate fixture of claim 12, further comprising a motor mount coupled to the small-substrate-size sub-assembly and the large-substrate-size sub-assembly, the motor mount being configured to rotate a substrate affixed to the multi-sized substrate fixture.

22. A multi-sized substrate fixture to accept at least two different sizes of substrates, the multi-sized substrate fixture comprising:
a small-substrate-size sub-assembly configured to affix a smaller one of the at least two different sizes of substrates;
a first plurality of substrate-edge grippers mechanically coupled to the small-substrate-size sub-assembly;
a large-substrate-size sub-assembly configured to affix a larger one of the at least two different sizes of substrates, the first plurality of substrate-edge grippers being configured to be extended and retracted through the large-substrate-size sub-assembly; and
a second plurality of substrate-edge grippers mechanically coupled to the large-substrate-size sub-assembly, the small-substrate-size sub-assembly mounted concentrically with the large-substrate-size sub-assembly.
